(19) United States
(12) Patent Application Publication
(10) Pub. No.: US 2013/0228659 A1
(43) Pub. Date: Sep. 5, 2013

(54) Support and Protection Device for Mobile Apparatus

(71) Applicant: Ching-Chang Wang, Tainan City (TW)

(72) Inventor: Ching-Chang Wang, Tainan City (TW)

(21) Appl. No.: 13/409,195

(22) Filed: Mar. 1, 2012

(51) Int. Cl. H05K 7/00; B60R 7/00; B62J 11/00

(52) U.S. Cl. 248/122.1; 224/412; 224/281

(57) ABSTRACT

A support and protection device for a mobile apparatus includes a mounting frame for receiving a mobile apparatus, and a support seat detachably connected with the mounting frame. The mounting frame has an entrance and a slideway. The support seat has a slide, a locking piece and a support portion. The support portion supports the support seat and the mounting frame. The locking piece is inserted into the entrance, and the slide is slidable in the slideway. Thus, the support and protection device can protect the mobile apparatus, and can also place the mobile apparatus on a horizontal plane so that the mobile apparatus will not be held by a user.

### BACKGROUND OF THE INVENTION

1. Field of the Invention

The present invention relates to a support device and, more particularly, to a support and protection device for a mobile apparatus, such as a cell phone and the like.

2. Description of the Related Art

A conventional protection device for a cell phone, such an i-phone and the like, comprises a back guard board and two side guard plates mounted on two opposite sides of back guard board. The back guard board has an upper end provided with at least one upper locking protrusion snapped onto the top of the cell phone and a lower end provided with at least one lower locking protrusion snapped onto the bottom of the cell phone. Thus, the cell phone is covered by the back guard board and the two side guard plates and is locked by the upper locking protrusion and the lower locking protrusion of the back guard board. However, the conventional protection device only has a protection function and cannot support the cell phone so that a user has to hold the cell phone, thereby causing inconvenience to the user when operating the cell phone in photographing or video recording.

### BRIEF SUMMARY OF THE INVENTION

In accordance with the present invention, there is provided a support and protection device, comprising a mounting frame, and a support seat detachably connected with the mounting frame. The mounting frame has a hollow interior provided with a receiving recess adapted for receiving a mobile apparatus. The mounting frame has a sidewall provided with an entrance and a slideway. The slideway of the mounting frame is connected to the entrance and has a width smaller than that of the entrance. The support seat has a first side provided with a slide and a second side provided with a support portion. The support portion of the support seat supports the support seat and the mounting frame when the support seat and the mounting frame are combined together. The slide of the support seat has a side provided with a locking piece. The locking piece of the support seat has a width greater than that of the slide and that of the slideway of the mounting frame. The locking piece of the support seat is inserted into the entrance of the mounting frame, and the slide of the support seat is slidable in the slideway of the mounting frame.

Preferably, the slideway of the mounting frame is located beside the entrance and is disposed at a middle position of the sidewall of the mounting frame.

Preferably, the slideway of the mounting frame has a distal end provided with a limit flange, and the locking piece of the support seat is movable to abut the limit flange of the mounting frame. Alternatively, the slideway of the mounting frame has a side provided with a locking groove, the locking groove of the mounting frame has a distal end provided with a limit flange, the locking groove of the mounting frame is connected to the entrance and has a width equal to that of the entrance, the locking piece of the support seat is slidable in the locking groove of the mounting frame after the locking piece of the support seat is inserted into the entrance of the mounting frame, and the locking piece of the support seat is movable in the locking groove of the mounting frame to abut the limit flange of the locking groove of the mounting frame.

Preferably, the support seat has a surface provided with a guide track slidably mounted on the mounting frame, the guide track of the support seat surrounds the sidewall of the mounting frame and has a width equal to a thickness of the mounting frame, and the slide and the locking piece of the support seat are disposed in the guide track. Preferably, the slide of the support seat is disposed between the support seat and the locking piece and is disposed at a middle position of the first side of the support seat. Preferably, the support portion of the support seat has a planar face.

The support portion of the support seat has an interior provided with a fastening hole which is exposed outward from the support portion of the support seat. Preferably, the fastening hole of the support seat is a screw bore. The support and protection device further comprises a supporting unit abutting the support portion of the support seat, and a fastening screw connected with the supporting unit and screwed into the fastening hole of the support seat to combine the supporting unit with the support seat. Preferably, the supporting unit is a stand or a fixture on a car or motorcycle.

The primary objective of the present invention is to provide a support and protection device for protecting and supporting a mobile apparatus

According to the primary advantage of the present invention, the support and protection device can surround and protect the mobile apparatus, and can also place the mobile apparatus on a horizontal plane so that the mobile apparatus will not be held by a user, thereby facilitating the user operating the mobile apparatus to perform its function, such as photographing, video tape recording and the like.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a perspective view of a support and protection device for a mobile apparatus in accordance with the preferred embodiment of the present invention.

FIG. 2 is an exploded perspective view of the support and protection device for a mobile apparatus as shown in FIG. 1.

FIG. 3 is a partially side cross-sectional view of the support and protection device for a mobile apparatus as shown in FIG. 1.

FIG. 4 is an operational view of the support and protection device for a mobile apparatus as shown in FIG. 3.

FIG. 5 is an operational view of the support and protection device for a mobile apparatus as shown in FIG. 4.

FIG. 6 is an exploded perspective view of a support and protection device for a mobile apparatus in accordance with another preferred embodiment of the present invention.

FIG. 7 is a side cross-sectional assembly view of the support and protection device for a mobile apparatus as shown in FIG. 6.

### DETAILED DESCRIPTION OF THE INVENTION

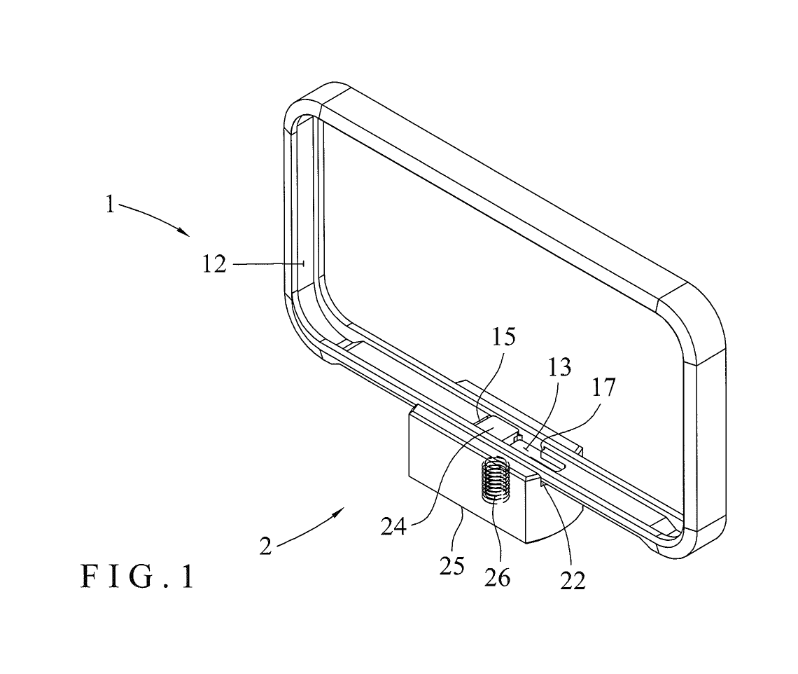

Referring to the drawings and initially to FIGS. 1-5, a support and protection device for a mobile apparatus in accordance with the preferred embodiment of the present invention comprises a mounting frame 1, and a support seat 2 detachably connected with the mounting frame 1.

The mounting frame 1 is used to receive a mobile apparatus, such as a cell phone, a global positioning system (GPS), a car video recorder and the like. Preferably, the cell phone is an i-phone. The mounting frame 1 has a hollow interior provided with a receiving recess 12 to receive the mobile apparatus. The mounting frame 1 has a sidewall provided with an entrance 13 and a slideway 14. Each of the entrance 13 and the slideway 14 of the mounting frame 1 is connected to the receiving recess 12. The slideway 14 of the mounting frame 1 is connected to the entrance 13 and has a width smaller than that of the entrance 13. The slideway 14 of the mounting frame 1 is located beside the entrance 13 and is disposed at a middle position of the sidewall of the mounting frame 1.

The slideway 14 of the mounting frame 1 has a side provided with a locking groove 15. The locking groove 15 of the mounting frame 1 has a distal end provided with a limit flange 16. The locking groove 15 of the mounting frame 1 is connected to the entrance 13 and has a width equal to that of the entrance 13. The entrance 13 of the mounting frame 1 has a side provided with a stop wall 17.

The support seat 2 may have a rectangular, polygonal, circular or other geometrical shape. The support seat 2 has a first side provided with a slide 23 and a second side provided with a support portion 25. The support portion 25 of the support seat 2 is preferably a weight to support the support seat 2 and the mounting frame 1 when the support seat 2 and the mounting frame 1 are combined together. The support portion 25 of the support seat 2 has a planar face and has an interior provided with a fastening hole 26 which is exposed outward from the support portion 25 of the support seat 2. Preferably, the fastening hole 26 of the support seat 2 is a screw bore.

The slide 23 of the support seat 2 has a side provided with a locking piece 24. The slide 23 of the support seat 2 is disposed between the support seat 2 and the locking piece 24 and is disposed at a middle position of the first side of the support seat 2. The locking piece 24 of the support seat 2 has a width greater than that of the slide 23 and that of the slideway 14 of the mounting frame 1. The locking piece 24 of the support seat 2 is inserted into the entrance 13 of the mounting frame 1, and the slide 23 of the support seat 2 is slidable in the slideway 14 of the mounting frame 1.

The locking piece 24 of the support seat 2 is stopped by the stop wall 17 of the entrance 13 of the mounting frame 1 and is slidable in the locking groove 15 of the mounting frame 1 after the locking piece 24 of the support seat 2 is inserted into the entrance 13 of the mounting frame 1. The locking piece 24 of the support seat 2 is movable in the locking groove 15 of the mounting frame 1 to abut the limit flange 16 of the locking groove 15 of the mounting frame 1 so as to stop movement of the support seat 2 relative to the mounting frame 1.

The support seat 2 has a surface provided with a guide track 22 slidably mounted on the mounting frame 1 to guide movement of the support seat 2 relative to the mounting frame 1. The guide track 22 of the support seat 2 has a substantially U-shaped profile to surround the sidewall of the mounting frame 1 and has a width equal to a thickness of the mounting frame 1. The slide 23 and the locking piece 24 of the support seat 2 are disposed in the guide track 22.

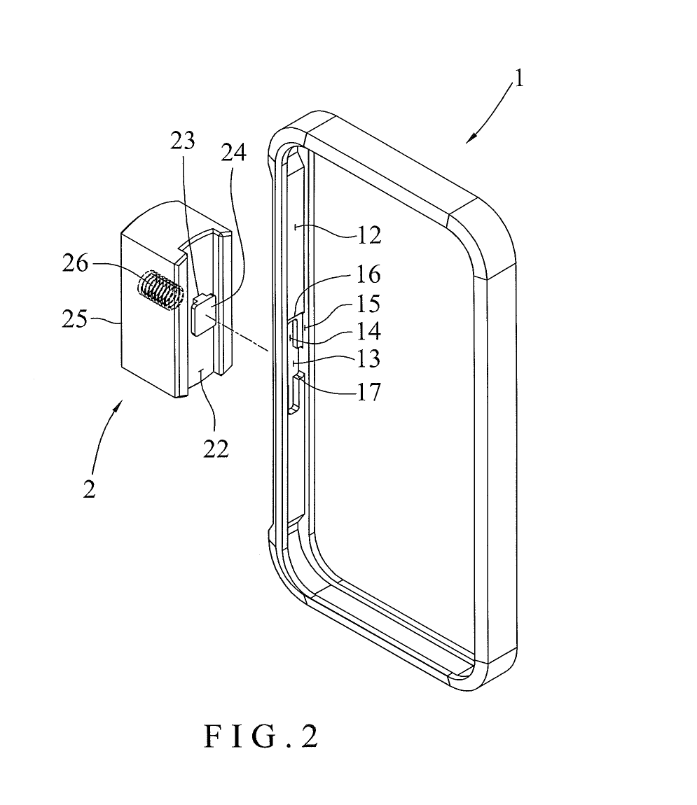

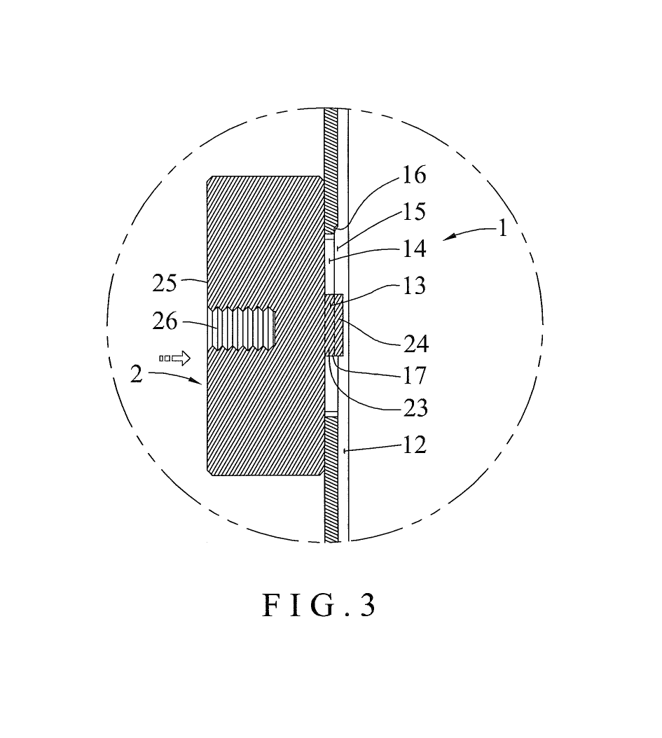

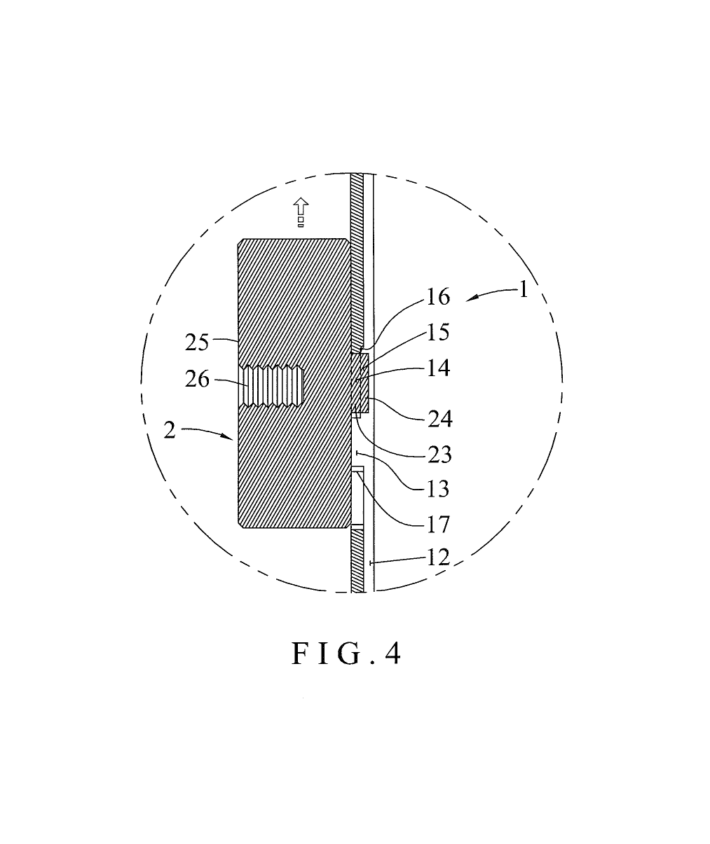

In operation, referring to FIGS. 3-5 with reference to FIGS. 1 and 2, after the locking piece 24 of the support seat 2 is inserted into the entrance 13 of the mounting frame 1 to align with the locking groove 15 of the mounting frame 1 as shown in FIG. 3, the slide 23 of the support seat 2 is extended into the slideway 14 of the mounting frame 1. Then, when the support seat 2 is moved upward relative to the mounting frame 1, the slide 23 of the support seat 2 is moved upward in the slideway 14 of the mounting frame 1, and the locking piece 24 of the support seat 2 is moved upward in the locking groove 15 of the mounting frame 1 to abut the limit flange 16 of the locking groove 15 of the mounting frame 1 as shown in FIG. 4 so as to stop the movement of the support seat 2 relative to the mounting frame 1. At this time, the locking piece 24 of the support seat 2 is locked in the locking groove 15 of the mounting frame 1 so that the support seat 2 is locked onto and combined with the mounting frame 1 as shown in FIG. 1. In such a manner, the support portion 25 of the support seat 2 is placed on a horizontal plane to support the mounting frame 1 so that the mobile apparatus received in the mounting frame 1 is supported by the support seat 2 and will not be held by a user, thereby facilitating the user operating the mobile apparatus to perform its function, such as photographing, video tape recording and the like.

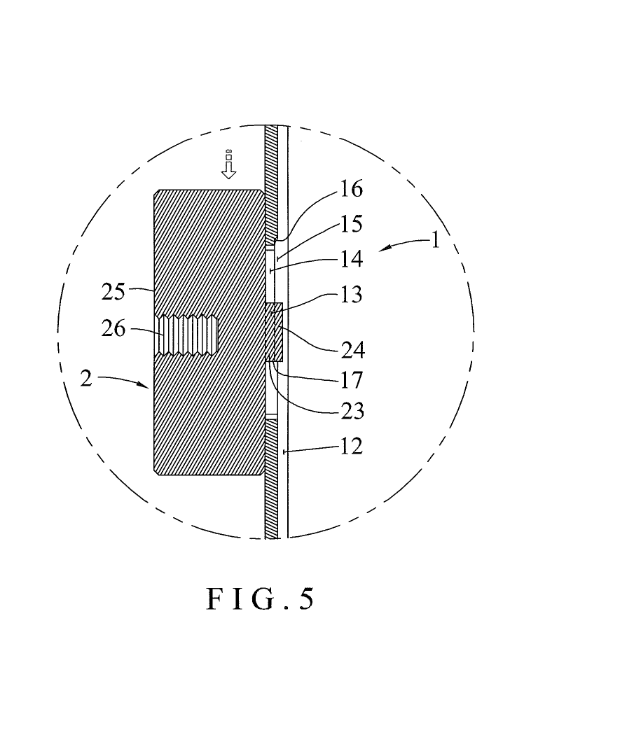

On the contrary, when the support seat 2 is moved downward relative to the mounting frame 1, the slide 23 of the support seat 2 is moved downward in the slideway 14 of the mounting frame 1, and the locking piece 24 of the support seat 2 is moved downward in the locking groove 15 of the mounting frame 1 to abut the stop wall 17 of the entrance 13 of the mounting frame 1 as shown in FIG. 5 so as to stop the movement of the support seat 2 relative to the mounting frame 1. At this time, the locking piece 24 of the support seat 2 is aligned with the entrance 13 of the mounting frame 1 to unlock the support seat 2 from the mounting frame 1 so that the locking piece 24 of the support seat 2 can be moved outward to detach from the entrance 13 of the mounting frame 1, and the support seat 2 can be removed from the mounting frame 1 as shown in FIG. 2.

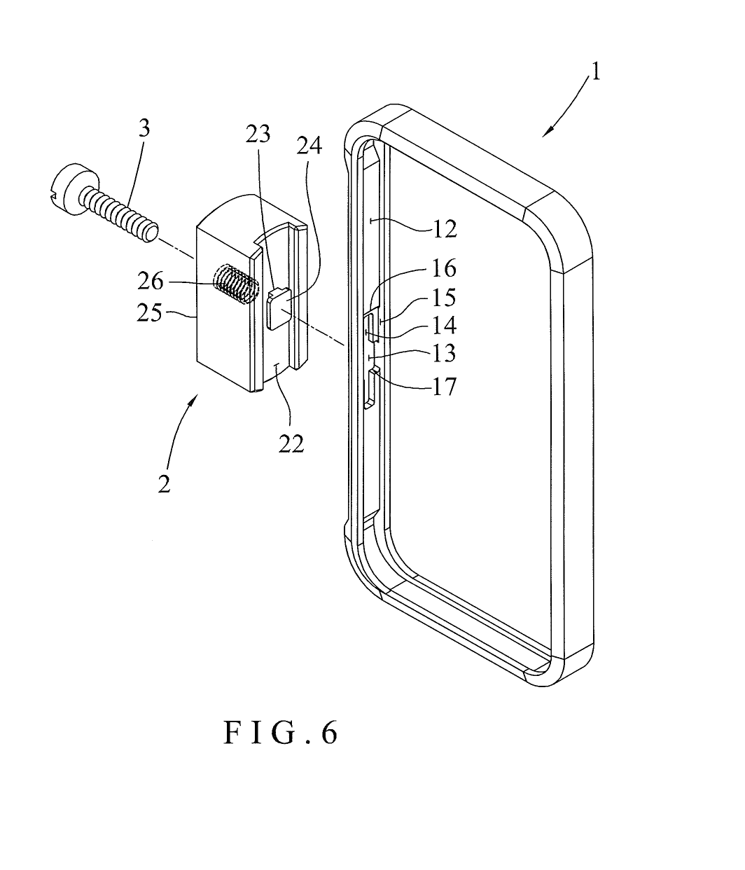

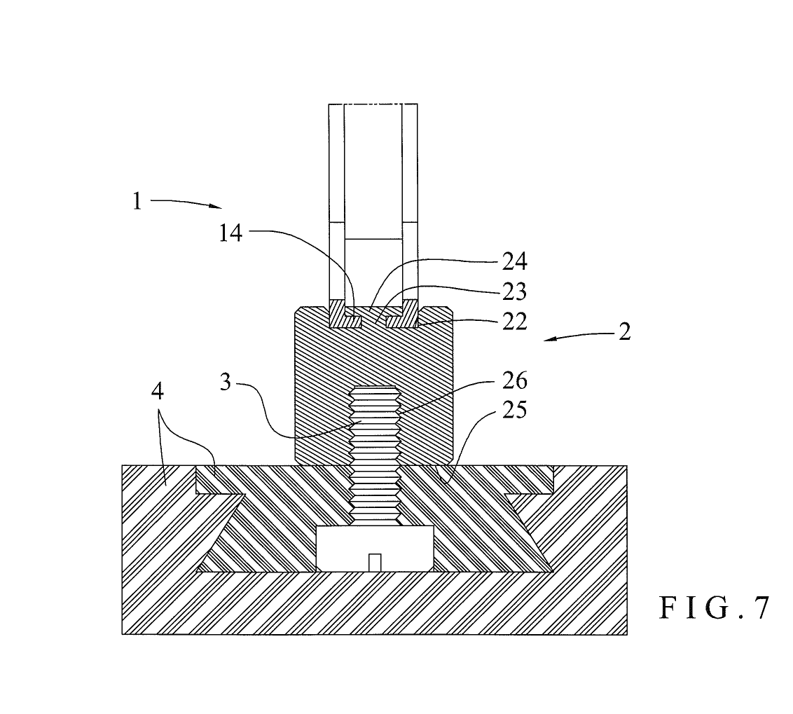

Referring to FIGS. 6 and 7, the support and protection device further comprises a supporting unit 4 abutting the support portion 25 of the support seat 2, and a fastening screw 3 connected with the supporting unit 4 and screwed into the fastening hole 26 of the support seat 2 to combine the supporting unit 4 with the support seat 2. Preferably, the supporting unit 4 is a stand or a fixture on a car or motorcycle. Thus, the mobile apparatus received in the mounting frame 1 is supported by the supporting unit 4 solidly and stably so that the mobile apparatus is used for outdoor photographing or video tape recording, and can be placed on a car or motorcycle to provide a function, such as navigation, car video recording and the like, thereby enhancing the versatility of the mobile apparatus.

Accordingly, the support and protection device can surround and protect the mobile apparatus, and can also place the mobile apparatus on a horizontal plane so that the mobile apparatus will not be held by a user, thereby facilitating the user operating the mobile apparatus to perform its function, such as photographing, video tape recording and the like. In addition, the mobile apparatus is supported by the supporting unit 4 of the support and protection device solidly and stably so that the mobile apparatus is used for outdoor photographing or video tape recording, and can be placed on a car or motorcycle to provide a function, such as navigation, car video recording and the like, thereby enhancing the versatility of the mobile apparatus.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A support and protection device, comprising:
a mounting frame; and
a support seat detachably connected with the mounting frame;
wherein the mounting frame has a hollow interior provided with a receiving recess adapted for receiving a mobile apparatus;
the mounting frame has a sidewall provided with an entrance and a slideway;
the slideway of the mounting frame is connected to the entrance and has a width smaller than a width of the entrance;
the support seat has a first side provided with a slide and a second side provided with a support portion;
the support portion of the support seat supports the support seat and the mounting frame when the support seat and the mounting frame are combined together;
the slide of the support seat has a side provided with a locking piece;
the locking piece of the support seat has a width greater than a width of the slide and the width of the slideway of the mounting frame;
the locking piece of the support seat is inserted into the entrance and the slideway of the mounting frame; and
the slide of the support seat is slidable in the slideway of the mounting frame.

2. The support and protection device of claim 1, wherein the slideway of the mounting frame is located beside the entrance and is disposed at a middle position of the sidewall of the mounting frame, and the slide of the support seat is inserted into the slideway of the mounting frame after the locking piece of the support seat is extended through the entrance of the mounting frame.

3. The support and protection device of claim 1, wherein the slideway of the mounting frame has a distal end provided with a fixed limit flange, and the locking piece of the support seat has an end that is movable to abut the limit flange of the mounting frame to stop movement of the locking piece relative to the mounting frame.

4. The support and protection device of claim 1, wherein the slideway of the mounting frame has a side provided with a locking groove, the locking groove of the mounting frame has a distal end provided with a fixed limit flange, the locking groove of the mounting frame is connected to the entrance and has a width equal to the width of the entrance, the locking piece of the support seat is slidable in the locking groove of the mounting frame after the locking piece of the support seat is inserted into the entrance of the mounting frame, and the locking piece of the support seat has an end that is movable in the locking groove of the mounting frame to abut the limit flange of the locking groove of the mounting frame to stop movement of the locking piece relative to the mounting frame.

5. The support and protection device of claim 1, wherein the support seat has a recessed surface abutting the sidewall of the mounting frame and provided with a substantially U-shaped guide track slidably mounted on the mounting frame, the guide track of the support seat surrounds the sidewall of the mounting frame and has a width equal to a thickness of the mounting frame, and the slide and the locking piece of the support seat are disposed in the guide track.

6. The support and protection device of claim 1, wherein the slide of the support seat is disposed between the support seat and the locking piece and is disposed at a middle position of the first side of the support seat.

7. The support and protection device of claim 1, wherein the support portion of the support seat has a planar face.

8. The support and protection device of claim 1, wherein the support portion of the support seat has an interior provided with a fastening hole which is exposed outward from the support portion of the support seat.

9. The support and protection device of claim 8, wherein the fastening hole of the support seat is a screw bore, and the support and protection device further comprises a supporting unit abutting and protruding outward from the support portion of the support seat, and a fastening screw connected with the supporting unit and screwed into the fastening hole of the support seat to combine the supporting unit with the support seat.

10. The support and protection device of claim 9, wherein the supporting unit is a stand or a fixture on a car or a motorcycle.
